(19) United States
(12) Patent Application Publication
(10) Pub. No.: US 2019/0056651 A1
(43) Pub. Date: Feb. 21, 2019

(54) EUV PATTERNING USING PHOTOMASK SUBSTRATE TOPOGRAPHY

(71) Applicant: GLOBALFOUNDRIES INC., GRAND CAYMAN (KY)

(72) Inventors: Erik Verduijn, Rensselaer, NY (US); Yulu Chen, West Sand Lake, NY (US); Lars Liebmann, Mechanicville, NY (US); Pawitter Mangat, Mesa, AZ (US)

(73) Assignee: GLOBALFOUNDRIES INC., GRAND CAYMAN (KY)

(21) Appl. No.: 15/681,491

(22) Filed: Aug. 21, 2017

(51) Int. Cl. G03F 1/24; G03F 1/72; G03F 1/84; G03F 7/40; H01L 21/033; H01L 21/3213

(52) U.S. Cl. CPC G03F 1/24; G03F 1/72; H01L 21/32139; G03F 7/40; H01L 21/0337; G03F 1/84

(57) ABSTRACT

A photomask includes a substrate having a top surface. A topographical feature is formed on the top surface of the substrate. The topographical feature may be a bump or a pit created on the top surface of the substrate. A reflector is formed on the top surface of the substrate over the topographical feature. The topographical feature warps the reflector in order to generate phase and/or amplitude gradients in light reflected off the reflector. An absorber is patterned on the reflector defining lithographic patterns for a resist material. The gradients in the light reflected off the reflector create shadow regions during lithography of the resist material using extreme ultraviolet (EUV) light.

### BACKGROUND

### Field of the Invention

The present invention relates to the field of semiconductor integrated circuit (IC) manufacturing, and more specifically, to a method for reducing tip-to-tip spacing between lines using a photomask that modifies the phase and/or amplitude of light for extreme ultraviolet (EUV) photolithography.

### Description of Related Art

Photolithography is commonly used to make miniaturized electronic components such as integrated circuits in semiconductor manufacturing. In a photolithography process, a layer of photoresist is deposited on a substrate, such as a silicon wafer. The substrate is baked to remove any solvent remained in the photoresist layer. The photoresist is then selectively exposed through a photo mask with a desired pattern to a source of radiation. The radiation exposure causes a chemical reaction in the exposed areas of the photoresist and creates a latent image corresponding to the photomask pattern in the photoresist layer. The photoresist is next developed in a developer solution to remove either the exposed portions of the photoresist for a positive photoresist or the unexposed portions of the photoresist for a negative photoresist. The patterned photoresist can then be used as a mask for subsequent fabrication processes on the substrate, such as deposition, etching, or ion implantation processes.

Advances in semiconductor device performance have typically been accomplished through a decrease in semiconductor device dimensions. The tip-to-tip spacing between lines (e.g., metal gates and back end of line metal wires) has a high impact on the unit cell density of the semiconductor device. Reducing the tip-to-tip distance between lines will greatly increase the unit cell density, which in turn will lead to shrinkage in the device dimension. However, due to the line end shortening issue and the resolution limitation of photolithography, the currently available optical lithographic techniques can only achieve a tip-to-tip distance of about 50 nm. With EUV lithography, approximately 20 nm can be achieved.

In the past, scaling of the chip has been accomplished by shrinking the dimensions of the devices in the substrate as well as the dimensions of the interconnections between the devices. Thus, a continual enhancement in photolithography has contributed to repeated reductions in a critical dimension (CD) that can be successfully patterned in a feature on a device.

However, as device dimensions continue to shrink, the fundamental limitations of optics play increasingly larger roles. In particular, diffraction will degrade an aerial image produced by the imaging system when the CD becomes smaller than the exposure wavelength. Consequently, resolution enhancement techniques (RETs) may be needed to achieve sufficiently wide process latitude when the CD becomes smaller than the wavelength of the EUV light.

The wavelength of light used for exposure of photoresist depends on the available illumination source and has been decreased over time from 436 nanometers (nm) to 365 nm (both being ultraviolet or UV light), and, subsequently, to 248 nm and then to 193 nm (both being deep ultraviolet or DUV light). Now, the exposure wavelength may be decreased to even shorter wavelengths, including extreme ultraviolet or EUV light, on the order of 10-15 nm.

Still, conventional EUV photomasks use a few light absorbing layers over a reflective blank to define lithographic patterns. The tip-to-tip structures are either formed from exposure of a single mask or exposure of lines from one photomask and creating the line-ends by means of a second “cut” mask. In either case, the ultimate resolution of the line-end is limited by the resolution attainable by absorber based mask technology.

### SUMMARY

Methods disclosed herein pattern the contours of an absorber based EUV photomask using etched or deposited (respectively pit or bump) structures on the photomask substrate to “cut” the lines and create tip-to-tip patterns. By virtue of the phase gradients generated in the light reflected off the reflector of the photomask by such pit or bump structures, a very sharply defined shadow region can be generated and used to pattern the cut. The ultimate resolution of the shadow region can be better than that attainable by conventional absorber based mask technology. The method enables EUV photomasks to print tip-to-tip constructs with smaller ultimate dimensions as compared to traditional EUV photomasks.

The structure disclosed herein is the photomask used in EUV lithography. The photomask uses mask substrate topography to generate finer tip-to-tip patterns than possible with conventional EUV photomasks. Conventional EUV photomasks use light absorbing layers over a reflective blank to define lithographic patterns, including tip-to-tip arrangements. The EUV photomask creates lines with conventional absorber based mask technology while using mask substrate topography (etched substrates or deposited bumps) to create fine shadows for tip-to-tip patterning.

A phase-shifting mask (PSM) is a type of resolution enhancement technique (RET). Unlike a conventional binary mask that only modulates the amplitude of light, a PSM also modulates the phase of light to use interference to mitigate the detrimental effects of diffraction and enhance resolution of the optics.

The fine shadow created by the pit or bump on the EUV photomask disclosed herein arise from the warped reflector region above topographical features formed on a substrate, creating light reflection with differences of phase and/or amplitude over a narrow region. The resultant reflected light from such a warped reflector region creates a narrow region of light-loss (shadow). In other words, the fine shadow region is created by the induced disturbance to the reflected light, which destroys the constructive interference condition from multiple layers in the reflector.

In view of the foregoing, disclosed herein is a photomask including a substrate having a top surface. A topographical feature is formed on the top surface of the substrate. The topographical feature may be a bump or a pit created on the top surface of the substrate. A reflector is formed on the top surface of the substrate over the topographical feature. The topographical feature warps the reflector in order to generate phase and/or amplitude gradients in light reflected off the reflector. An absorber is patterned on the reflector defining lithographic patterns for a resist material. The gradients in the light reflected off the reflector create shadow regions during lithography of the resist material using extreme ultraviolet (EUV) light.

Also disclosed herein is a method for reducing tip-to-tip spacing between lines using topography in the substrate of the photomask to generate cuts in absorber patterned lines. Specifically, in the method, a substrate is provided. The substrate has a top surface. A topographical feature is formed on the top surface of the substrate. A reflector is formed on the top surface of the substrate over the topographical feature. The topographical feature warps the reflector in order to generate phase and/or amplitude gradients in light reflected off the reflector. A masking material is deposited on the reflector corresponding to mask patterns of an extreme ultraviolet (EUV) photomask for a line structure. Reflective EUV lithography is performed using the EUV photomask. The gradients in the light reflected off the reflector define shadow regions for the EUV photomask to create line-end-to-line-end spacing in the line structure.

More particularly, disclosed herein are embodiments of a method of forming an extreme ultraviolet (EUV) photomask and performing reflective EUV lithography using the EUV photomask. In the method, a substrate is provided. The substrate has a top surface. A periphery of the top surface is defined and fiducial markers are etched on the top surface of the substrate in the periphery. A topographical feature is formed on the top surface of the substrate. The topographical feature is aligned with the fiducial markers outside the periphery. A multilayer reflector is formed on the top surface of the substrate over the topographical feature. The topographical feature warps the reflector in order to generate phase and/or amplitude gradients in light reflected off the multilayer reflector. An absorber is deposited on the multilayer reflector. The absorber has light absorbing layers that define lithographic patterns corresponding to an EUV photomask for a line structure having line-end to line-end spacing at the point of the topographical feature aligned with respect to the fiducial markers. Reflective EUV lithography is performed using the EUV photomask. The phase and/or amplitude gradients in the multilayer reflector define shadow regions for the EUV photomask to create the line-end-to-line-end spacing in the line structure.

Generally, the method embodiments include forming a topographical feature on a substrate to subsequently define shadow regions for the EUV photomask in order to create the line-end-to-line-end spacing in the line structure. The photomask includes multiple alternating layers of high refractive material and low refractive material, which are warped by the topographical feature. Light absorbing layers are deposited over the reflective blank to define lithographic patterns, including tip-to-tip spacing. Fine shadows created by the topographical feature arise from the warped reflector region above the topographical feature, creating light reflection with differences of phase and/or amplitude of the light over a narrow region. The resultant reflected light from such a warped reflector region creates a narrow region of light-loss (shadow) that can bed used to produce the tip-to-tip pattern.

Such devices methods can be used during the formation of a variety of IC structures and could enable more aggressive scaling for some critical constructs such as tip-to-tip in various technology nodes.

### BRIEF DESCRIPTION OF THE SEVERAL VIEWS OF THE DRAWINGS

Various examples of the devices and methods of the present invention will be better understood from the following detailed description with reference to the accompanying drawings, which are not necessarily drawn to scale and in which:

FIG. 1A shows a side view of an extreme ultraviolet (EUV) photomask, according to devices and methods herein;

FIG. 1B shows a top view of the photomask of FIG. 1A, according to devices and methods herein;

FIG. 1C shows a top view of etch results using the photomask of FIG. 1A, according to devices and methods herein;

FIG. 2A is a top view of a substrate with a topographical feature, according to devices and methods herein;

FIG. 2B is a cross-section view of the substrate with a topographical feature created by deposition, taken along the line X-X of FIG. 2A;

FIG. 2C is a cross-section view of the substrate with a topographical feature created by etching, taken along the line X-X of FIG. 2A;

FIG. 3A is a top view of an EUV photomask, according to devices and methods herein;

FIG. 3B is a cross-section view of the EUV photomask, taken along the line Y-Y of FIG. 3A;

FIG. 4 is a side view of an EUV photomask, according to devices and methods herein;

FIG. 5A is a top view of an EUV photomask, according to devices and methods herein;

FIG. 5B is a cross-section view of the EUV photomask, taken along the line Y-Y of FIG. 5A;

FIG. 5C is a cross-section view of the EUV photomask, taken along the line Z-Z of FIG. 5A; and

FIG. 6 is a flow chart according to methods herein.

### DETAILED DESCRIPTION

The following detailed description of the devices and methods, as represented in the drawings, is not intended to limit the scope defined by the appended claims, but is merely representative of selected devices and methods. The following description is intended only by way of example, and simply illustrates certain concepts of the devices and methods, as disclosed and claimed herein.

As mentioned above, line-end-to-line-end (a.k.a. tip-to-tip) patterns where two patterned lines meet and are separated by a small width are critical constructs in lithography. Achieving the desired small separation has been a challenge with conventional lithographic techniques. Conventional EUV masks use a few light absorbing layers over a reflective blank to define the lithographic patterns. Typically, the line-end-to-line-end spacing is formed from exposure of a single mask or exposure of lines from one photomask and creating the line-ends by means of a second “cut” mask. In either case, the ultimate resolution of the line-end-to-line-end spacing is limited by the resolution attainable by absorber based mask technology. In other words, the light loss for lithographic patterning is achieved by the light absorber on the surface of the reflector.

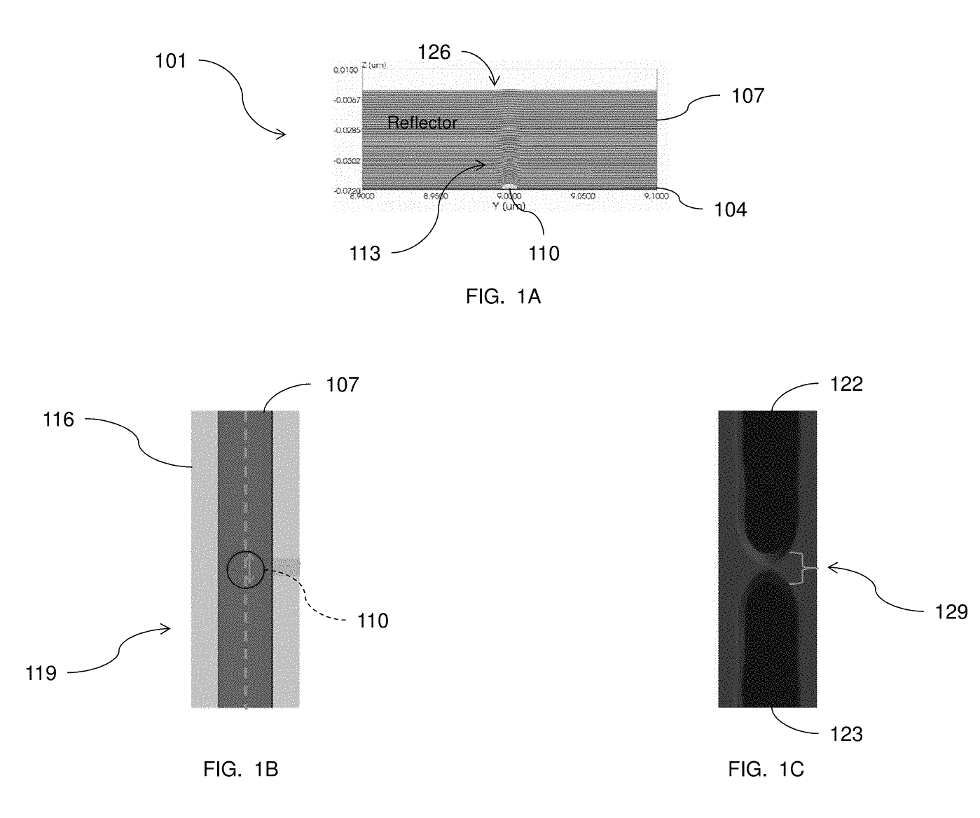

In view of the foregoing, devices and methods herein use the conventional method of patterning the lines; but topographical features on the photomask substrate are used to “cut” the lines and create the tip-to-tip patterns. Referring to FIG. 1A, an EUV photomask according to devices and methods herein, indicated generally as 101, includes a substrate 104 with a reflector 107. A structure 110 (pit or bump, respectively) is formed on the substrate 104 by etching or deposition. The structure causes warping of the reflector 107, indicated generally as 113. The warping 113 generates phase and/or amplitude gradients in light reflected off the reflector 107. As shown in FIG. 1B, a light absorber 116 is formed over the reflector 107. A resist mask 119 is patterned on the light absorber 116 to define lines 122, 123. By virtue of the gradients generated in the light reflected off the reflector 107 by the structure 110, a very sharply defined shadow region 126 can be generated. The shadow region 126 can be used to pattern the end-to-end line spacing, indicated at 129, shown in FIG. 1C. That is, as shown in FIGS. 1A-1C, light loss for lithographic patterning is achieved by the differences in the reflected light caused by warping 113 of the reflector 107.

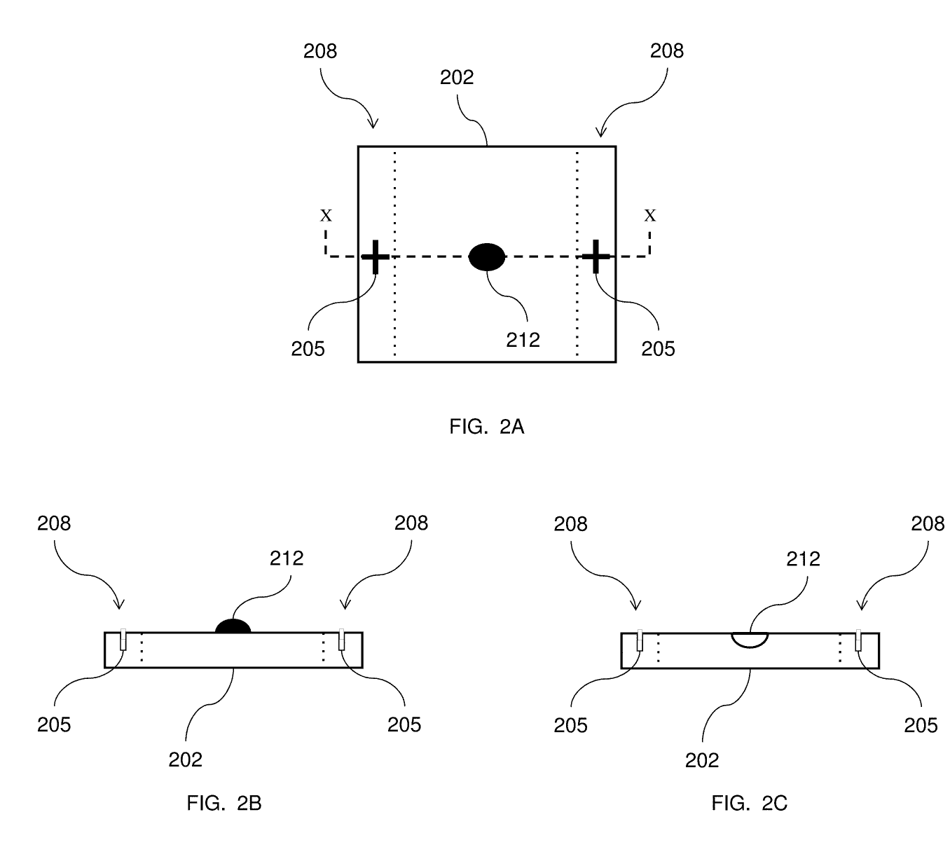

The next several figures illustrate the processing steps for forming an extreme ultraviolet (EUV) photomask, according to devices herein. In FIGS. 2A-2C, a substrate 202 is provided. The substrate 202 may be any conventional substrate such as, for example, an ultra low-k material. An ultra low-k material is a material with a very small dielectric constant relative to silicon dioxide. The substrate 202 should have a smooth surface, without defects, and a low coefficient of thermal expansion (CTE). For example, the substrate 202 may be a glass or ceramic material.

Alignment fiducials 205 may be etched in a periphery 208 of the substrate 202. The alignment fiducials 205 may be located on the four corners of the substrate 202, in the periphery 208. The alignment fiducials 205 may be transferred to substrate 202 using standard lithography techniques, such as by patterning and etching using a hardmask, for example.

A hardmask can be formed of any suitable material, whether now known or developed in the future, such as a metal or organic or inorganic (Si3N4, SiC, SiO2C (diamond)) hardmask, that has etch resistance greater than the substrate and materials used in the remainder of the structure. When patterning any material herein, the material to be patterned can be grown or deposited in any known manner and a patterning layer (such as an organic photoresist) can be formed over the material. The patterning layer (resist mask) can be exposed to some pattern of light radiation (e.g., patterned exposure, laser exposure, etc.) provided in a light exposure pattern, and then the resist is developed using a chemical agent. This process changes the physical characteristics of the portion of the resist that was exposed to the light. Then one portion of the resist can be rinsed off, leaving the other portion of the resist to protect the material to be patterned (which portion of the resist that is rinsed off depends upon whether the resist is a positive resist (illuminated portions remain) or negative resist (illuminated portions are rinsed off). A material removal process is then performed (e.g., plasma etching, etc.) to remove the unprotected portions of the material below the resist to be patterned. The resist is subsequently removed to leave the underlying material patterned according to the light exposure pattern (or a negative image thereof).

A topographical feature 212 is formed on the substrate 202. The topographical feature 212 may be created by material deposition added to the substrate 202 (i.e., a bump, raised portion, dome, rounded strip, elevation, etc., as shown in FIG. 2B) or material removal from the substrate 202, such as etching (i.e., a pit, recess, ditch, cavity, indentation, etc., as shown in FIG. 2C). Therefore, the topographical feature 212 extends from the plane of the surface of the substrate 202 upon which it is formed; or stated differently, the topographical feature 212 extends out of, or into, such a plane (and can be considered convex or concave with respect to such a plane). Further, the topographical feature 212 can have any appropriate three-dimensional shape, such as a partial sphere, cone, pyramid, tetrahedron, partial ellipsoid, etc. For example, the topographical feature 212 can be created by depositing a material on the substrate 202, such as by depositing a blanket of material, applying a pattern to the blanket of material by standard lithography, and etching the blanket of material to form the topographical feature 212 having a predetermined size and shape, such as shown in FIG. 2B. In some cases, the topographical feature 212 may be created by forming a pit in the substrate 202, for example by patterning and etching, such as shown in FIG. 2C. Alternatively, focused ion beam, also known as FIB, can be used for deposition and/or ablation of materials. The alignment fiducials 205 may be used to accurately align the topographical feature 212 on the substrate 202. The topographical feature 212 may be any appropriate material (e.g., glass, ceramics, oxides, plastics, metals, etc.) sized and shaped to generate the sharply defined shadow region 126 for an appropriate “cut.” It is contemplated that more than one topographical feature may be used, and differently shaped and/or sized topographical features may be used within a single photomask.

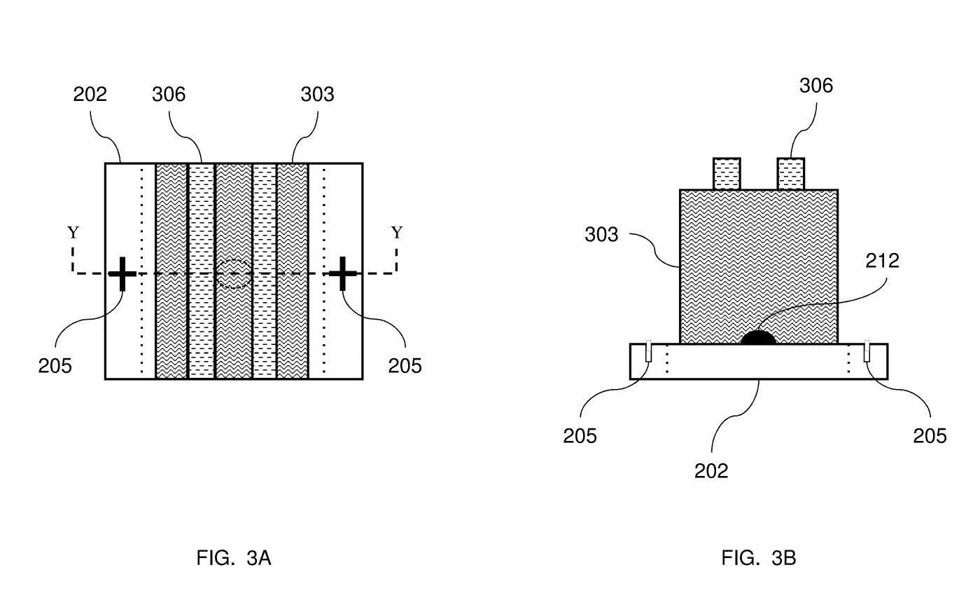

In FIGS. 3A and 3B, a reflector 303 is formed on the top surface of the substrate 202. An absorber 306 is deposited on the reflector 303 and patterned corresponding to mask patterns to be applied to a resist material. In the specific example of FIGS. 3A and 3B, the mask patterns may be for a line structure on the resist material. The pattern of the absorber 306 may be aligned to the alignment fiducials 205, which makes it aligned to the topographical feature 212.

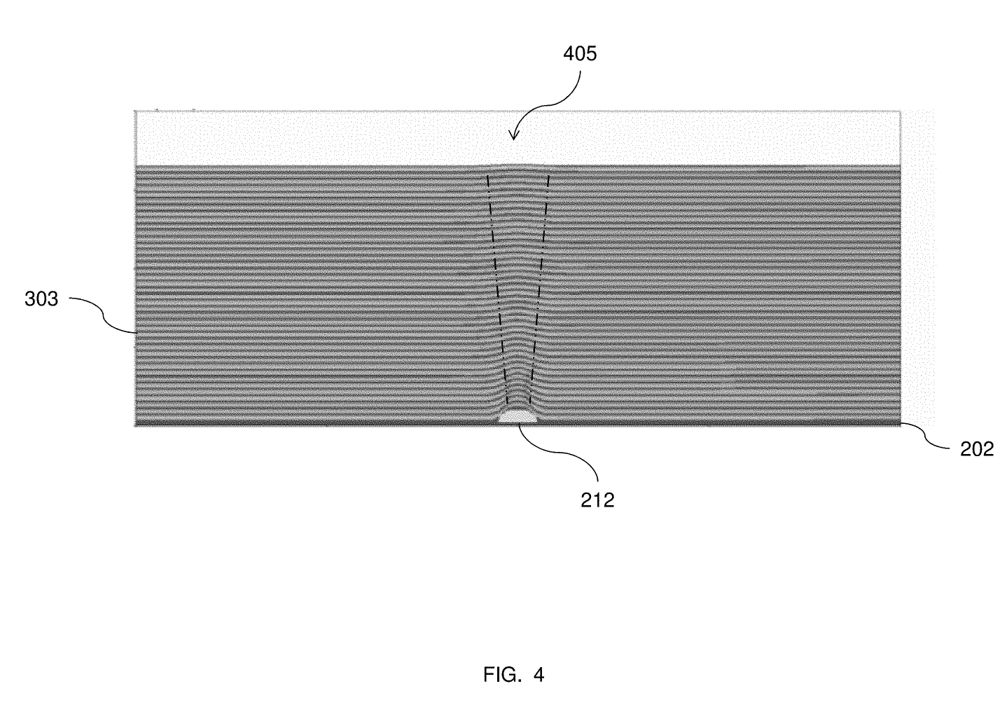

Referring to FIG. 4, the reflector 303 may be formed from alternating layers of materials that have dissimilar indexes of refraction. That is, one material having a high index of refraction (high refractive material) and another material having a low index of refraction (low refractive material). The high refractive material bends or scatters light at the illumination wavelength. The high refractive material may include one or more elements with a high atomic number (Z). In some cases, the high refractive material may be a metal, such as molybdenum (Z=42). The high refractive material may be crystalline, polycrystalline, or amorphous. The low refractive material transmits light at the illumination wavelength. The low refractive material may include one or more elements with a low atomic number (Z). The low refractive material may be silicon (Z=14). The low refractive material should have minimal absorption at the illumination wavelength. The low refractive material may also be crystalline, polycrystalline, or amorphous. Other materials, such as beryllium (Z=4) or ruthenium (Z=44), may be used. That is, the reflector 303 may be formed from multiple alternating layers of pairs of material, a first layer of each pair being a first material with a high index of refraction and a second layer of each pair being a second material with a low index of refraction. Additionally, intermediate layers may be disposed on some or all interfaces between the layers, for example molybdenum/ruthenium/silicon or molybdenum/carbon/silicon. In some cases, intermediate layers may be formed naturally by reaction of the different materials. The reflector 303 may include 10-50 pairs of alternating layers of high refractive material and low refractive material.

An interface between the high refractive material and the low refractive material in the reflector 303 should remain chemically and physically stable during fabrication. The interface between the high refractive material and the low refractive material in the reflector 303 should also remain chemically and physically stable during exposure to EUV light. Any interdiffusion at the interface between the high refractive material and the low refractive material in the reflector 303 should be minimized since the optical properties of the reflector 303 are more optimal when the individual layers are smooth and the transitions between the different materials are abrupt.

As each layer is applied to the substrate 202, the layer conforms to the topographical feature 212 on the substrate 202, which causes a warped region of the reflector 303, indicated generally as 405. The warped region 405 generates phase and/or amplitude gradients in light reflected off the reflector 303. Typically, a binary mask (i.e., one made of two materials having dissimilar indexes of refraction) modulates the amplitude of the exposure light. Therefore, diffraction of the exposure light will degrade the fidelity of the printed feature as the dimension to be printed approaches the wavelength of the exposure light. However, a phase gradient modulates the phase of the exposure light, in addition to the amplitude of the exposure light. All materials have defined optical properties, which describe the absorption, the reflection, or the phase shift of radiation that hits or impacts a material. If the thickness or the configuration of a material varies locally, for instance, due to the topographical feature 212 causing warping of the reflector 303, local differences in the radiation crossing the material or being reflected by the material are caused. These differences affect the amplitude and/or the phase of the crossing or reflected radiation. The resultant reflected light from the warped region 405 of the reflector 303 creates a narrow region of light-loss (shadow). The fine shadows created by the topographical feature 212 arise from the warped region 405 above the topographical feature 212, creating light reflection with differences of phase over a narrow region. The phase gradient can resolve dimensions of a feature that is about the same size as or smaller than the wavelength of the exposure light. The size of the topographical feature 212 and the number of layers and the relative thickness of each layer may be tuned to create specifically defined shadows during exposure to EUV light.

The absorber 306 may be an absorbing or reflective material and may include a stack of different materials in layers. The absorber 306 may, for instance, be a metal, such as chromium, tantalum, titanium, aluminum, or tungsten, a metal compound, such as TaN, TaBN, TaSix, or TiN, or a material selected from the group of zirconium, molybdenum, beryllium, carbon, or silicon oxides or nitrides. The absorber 306 may be patterned corresponding to mask patterns of a EUV photomask. In particular, the absorber 306 may be patterned corresponding to mask patterns of a line structure.

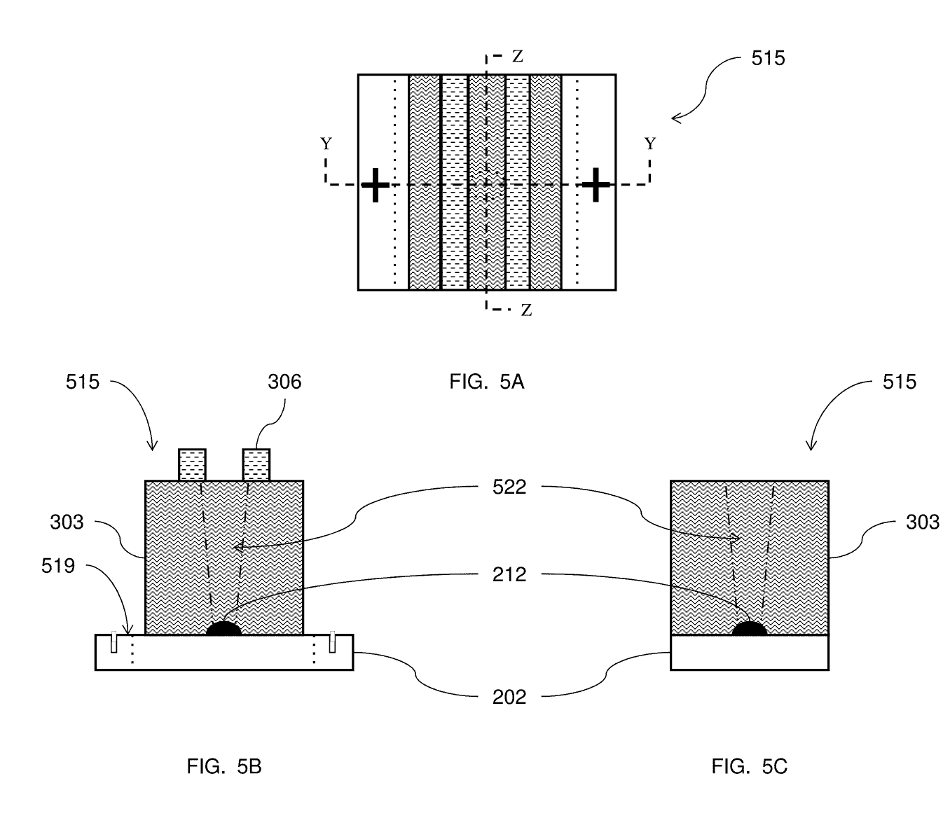

FIG. 5A shows a top view of an extreme ultraviolet (EUV) photomask 515, according to devices herein. The EUV photomask 515 includes a substrate 202, shown in FIGS. 5B and 5C. The substrate 202 has a top surface 519. A topographical feature 212 is formed on the top surface 519 of the substrate 202. The topographical feature 212 may be a bump or a pit created on the top surface 519 of the substrate 202. A reflector 303 is formed on the top surface 519 of the substrate 202 over the topographical feature 212. As shown in FIG. 5, the reflector 303 may be formed from alternating layers of materials that have dissimilar indexes of refraction. The topographical feature 212 warps the reflector 303 in order to generate phase and/or amplitude gradients in light reflected off the reflector 303. An absorber 306 is patterned on the reflector 303 defining lithographic patterns for a resist material. The warping of the reflector 303 generates phase and/or amplitude gradients in the light reflected off the reflector 303, which creates shadow regions during lithography of the resist material using extreme ultraviolet (EUV) light. Light loss for patterning achieved by the warped reflector is indicated at 522.

It should be understood that the techniques described above for forming the EUV photomask 515 are offered for illustration purposes only and are not intended to be limiting. Alternatively, any other suitable technique for forming the EUV photomask 515 could be used.

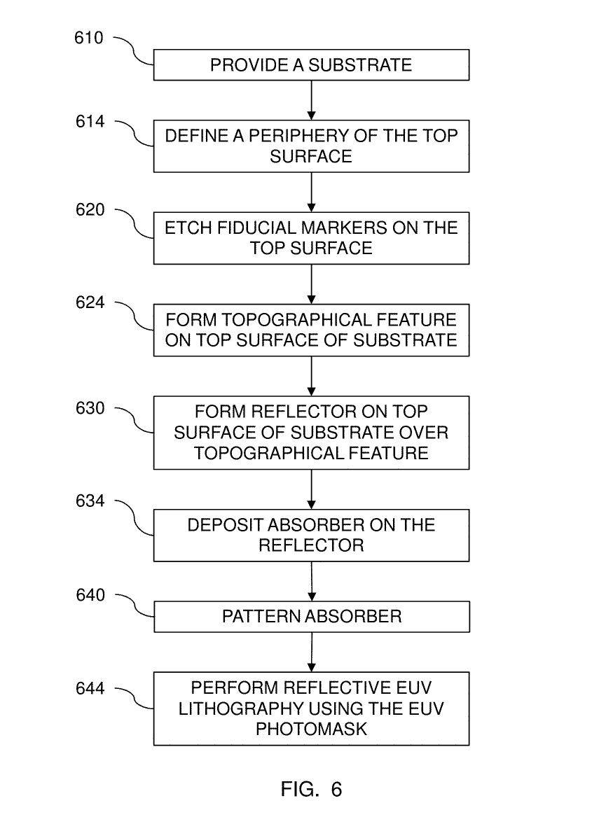

FIG. 6 is a flow diagram illustrating the processing flow of an exemplary a method of forming an extreme ultraviolet (EUV) photomask and performing reflective EUV lithography using the EUV photomask. At 610, a substrate is provided. The substrate has a top surface and may be an ultra low-k material. At 615, a periphery of the top surface is defined and fiducial markers are etched on the top surface of the substrate in the periphery, at 620. At 625, a topographical feature is formed on the top surface of the substrate. The topographical feature may be formed by depositing a material on the substrate or by forming a pit in the substrate and may be any appropriate material, size, or shape. In any event, the topographical feature should be aligned with the fiducial markers outside the periphery. At 630, a reflector is formed on the top surface of the substrate over the topographical feature. The reflector may be made of multiple alternating layers of high refractive material and low refractive material. The topographical feature warps the reflector so that light reflected off the reflector has phase and/or amplitude gradients, which creates shadow regions. At 635, an absorber is deposited on the reflector. At 640, the absorber is patterned using a resist mask to define lithographic patterns corresponding to an EUV photomask for a line structure having line-end-to-line-end spacing at the point of the fiducial markers. At 645, reflective EUV lithography is performed using the EUV photomask. The phase and/or amplitude gradients in the light reflected off the reflector define shadow regions for the EUV photomask to create the line-end-to-line-end spacing in the line structure.

While some exemplary structures are illustrated in the attached drawings, those ordinarily skilled in the art would understand that the drawings are simplified schematic illustrations and that the claims presented below encompass many more features that are not illustrated (or potentially many less) but that are commonly utilized with such devices and systems. Therefore, it is not intended for the claims presented below to be limited by the attached drawings, but instead the attached drawings are merely provided to illustrate a few ways in which the claimed features can be implemented.

The terminology used herein is for the purpose of describing particular devices and methods only and is not intended to be limiting of this disclosure. As used herein, the singular forms “a”, “an”, and “the” are intended to include the plural forms as well, unless the context clearly indicates otherwise. It will be further understood that the terms “comprises”, “comprising”, “includes”, and/or “including”, specify the presence of stated features, integers, steps, operations, elements, and/or components, but do not preclude the presence or addition of one or more other features, integers, steps, operations, elements, components, and/or groups thereof.

In addition, terms such as “right”, “left”, “vertical”, “horizontal”, “top”, “bottom”, “upper”, “lower”, “under”, “below”, “underlying”, “over”, “overlying”, “parallel”, “perpendicular”, etc., used herein, are understood to be relative locations as they are oriented and illustrated in the drawings (unless otherwise indicated). Terms such as “touching”, “on”, “in direct contact”, “abutting”, “directly adjacent to”, etc., mean that at least one element physically contacts another element (without other elements separating the described elements). Further, the terms “automated” or “automatically” mean that once a process is started (by a machine or a user), one or more machines perform the process without further input from any user.

The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element.

The corresponding structures, materials, acts, and equivalents of all means or step plus function elements in the claims below are intended to include any structure, material, or act for performing the function in combination with other claimed elements as specifically claimed. The descriptions of the various devices and methods of the present disclosure have been presented for purposes of illustration, but are not intended to be exhaustive or limited to the devices and methods disclosed. Many modifications and variations will be apparent to those of ordinary skill in the art without departing from the scope and spirit of the described devices and methods. The terminology used herein was chosen to best explain the principles of the devices and methods, the practical application or technical improvement over technologies found in the marketplace, or to enable others of ordinary skill in the art to understand the devices and methods disclosed herein.

The descriptions of the various embodiments of the present invention have been presented for purposes of illustration, but are not intended to be exhaustive or limited to the embodiments disclosed. It will be appreciated that the above-disclosed and other features and functions, or alternatives thereof, may be desirably combined into many other different systems or applications. Many modifications and variations will be apparent to those of ordinary skill in the art without departing from the scope and spirit of the described embodiments. Indeed, various presently unforeseen or unanticipated alternatives, modifications, variations, or improvements therein may be subsequently made by those skilled in the art which are also intended to be encompassed by the following claims. The terminology used herein was chosen to best explain the principles of the embodiments, the practical application or technical improvement over technologies found in the marketplace, or to enable others of ordinary skill in the art to understand the embodiments disclosed herein. However, unless specifically defined in a specific claim itself, steps or components of the devices and methods herein cannot be implied or imported from any above example as limitations to any particular order, number, position, size, shape, angle, color, or material.

What is claimed is:

1. A photomask, comprising:
a substrate having a top surface;
a topographical feature formed on the top surface of the substrate;
a reflector on the top surface of the substrate over the topographical feature, the reflector being warped by the topographical feature on the top surface of the substrate; and
an absorber patterned on the reflector defining lithographic patterns for a resist material,
wherein the warp in the reflector generates gradients in at least one of phase and amplitude of light reflected off the reflector to create shadow regions during lithography of the resist material using extreme ultraviolet (EUV) light.

2. The photomask according to claim 1, the topographical feature comprising one of a bump on the substrate and a pit in the substrate.

3. The photomask according to claim 1, the reflector further comprising:
multiple alternating layers of high refractive material and low refractive material.

4. The photomask according to claim 3, the high refractive material comprising molybdenum or ruthenium, and the low refractive material comprising silicon or beryllium.

5. The photomask of claim 1,
wherein the EUV light has a wavelength of approximately 13.5 nm.

6. The photomask of claim 1, the substrate comprising ultra low-k material.

7. The photomask according to claim 6, the substrate further comprising:
fiducials etched in a top surface of the substrate, the topographical feature being aligned with the fiducials.

8. A method comprising:
providing a substrate having a top surface;
forming a topographical feature on the top surface of the substrate;
forming a reflector on the top surface of the substrate over the topographical feature, the topographical feature creating a warp in the reflector during formation of the reflector;
depositing an absorber on the reflector;
patterning the absorber corresponding to mask patterns of a line structure, wherein the substrate, the reflector, and the absorber form an extreme ultraviolet (EUV) photomask; and
performing reflective EUV lithography using the EUV photomask and EUV light to pattern the line structure in a resist material,
during the reflective EUV lithography, the warp in the reflector creates shadow regions from the EUV light reflected off the reflector for the EUV photomask to create line-end-to-line-end spacing in the line structure of the resist material.

9. The method of claim 8, wherein the topographical feature comprises one of a bump on the substrate and a pit in the substrate.

10. The method according to claim 8, the forming a topographical feature on the top surface of the substrate further comprising:
depositing material on the top of the substrate;
applying a lithographic pattern on the material on the top of the substrate, the lithographic pattern defining a predetermined size and shape for the topographical feature; and
etching the material according to the lithographic pattern.

11. The method according to claim 8, the forming a reflector on the top surface of the substrate further comprising:
forming multiple alternating layers of pairs of material, a first layer of each pair comprising a first material with a high index of refraction and a second layer of each pair comprising a second material with a low index of refraction.

12. The method of claim 11, the reflector comprising 10-50 pairs of alternating layers of material.

13. The method according to claim 11, the high refractive material comprising molybdenum or ruthenium, and the low refractive material comprising silicon or beryllium.

14. The method of claim 8, further comprising:
etching fiducial markers in a periphery of the top surface of the substrate; and
aligning the topographical feature with the fiducial markers.

15. The method according to claim 8, wherein the performing reflective EUV lithography uses EUV light having a wavelength of approximately 13.5 nm.

16. A method comprising:
providing a substrate having a top surface;
defining a periphery of the top surface and etching fiducial markers on the top surface of the substrate in the periphery;
forming a topographical feature on the top surface of the substrate, the topographical feature comprising one of a bump on the substrate and a pit in the substrate, the topographical feature being aligned with the fiducial markers outside the periphery;
forming a reflector on the top surface of the substrate over the topographical feature, the topographical feature creating a warp in the reflector during formation of the reflector;
depositing a light absorber on the reflector;
patterning the light absorber corresponding to lithographic patterns for a line structure having spacing where the topographical feature is aligned with the fiducial markers, wherein the substrate, the reflector, and the light absorber form an extreme ultraviolet (EUV) photomask; and
performing reflective EUV lithography using the EUV photomask and EUV light to pattern the line structure in a resist material,
during the reflective EUV lithography, the warp in the reflector creates shadow regions from the EUV light reflected off the reflector for the EUV photomask to create line-end-to-line-end spacing in the line structure of the resist material.

17. The method according to claim 16, the forming a topographical feature on the top surface of the substrate further comprising:
depositing a material on the top of the substrate;
applying a lithographic pattern on the material on the top of the substrate, the lithographic pattern defining a predetermined size and shape for the topographical feature; and
etching the material according to the lithographic pattern.

18. The method according to claim 16, the forming a reflector on the top surface of the substrate further comprising:
forming multiple alternating layers of pairs of material, a first layer of each pair comprising a first material with a high index of refraction and a second layer of each pair comprising a second material with a low index of refraction, the reflector comprising 10-50 pairs of alternating layers of material.

19. The method according to claim 18, the high refractive material comprising molybdenum or ruthenium, and the low refractive material comprising silicon or beryllium.

20. The method according to claim 16, wherein the performing reflective EUV lithography uses EUV light having a wavelength of approximately 13.5 nm.
